(19) United States
(12) Patent Application Publication
(10) Pub. No.: US 2024/0202392 A1
(43) Pub. Date: Jun. 20, 2024

(54) SIMULATED ANNEALING DEVICE AND SIMULATED ANNEALING METHOD

(71) Applicant: NEC Corporation, Minato-ku, Tokyo (JP)

(72) Inventor: Yuta IDEGUCHI, Tokyo (JP)

(73) Assignee: NEC Corporation, Minato-ku, Tokyo (JP)

(21) Appl. No.: 18/287,098

(22) PCT Filed: Apr. 28, 2021
(86) PCT No.: PCT/JP2021/017018

§ 371 Date: Oct. 16, 2023

(51) Int. Cl. G06F 30/20

(52) U.S. Cl. CPC G06F 30/20

(57) ABSTRACT

A simulated annealing device for solving a combinatorial optimization problem by a simulated annealing scheme includes a confirmation unit which executes a process of confirming whether a flip is accepted or not for each of n spins from {(k−1)·n+1}-th to k·n-th that constitute an energy function in the Ising model representing the combinatorial optimization problem in parallel with a parallel number n, an updating unit which, when the acceptance of a flip on m-th spin (m is an integer between {(k−1)·n+1} and k·n) is confirmed first, updates change amount in energy of a spin associated with the m-th spin with the m-th spin flipped, and a changing unit which changes spins in which the next process of confirming is executed and the parallel number to spins from (m+1)-th to k·n-th and (n−m), respectively.

### TECHNICAL FIELD

The present invention relates to a simulated annealing device, a simulated annealing method, and a simulated annealing program.

### BACKGROUND ART

The practical application of quantum annealing machines has triggered renewed interest in a study on combinatorial optimization problems. Combinatorial optimization problems are problems of finding optimal combinations. Examples of combinatorial optimization problems that represent real-world problems include the traveling salesman problem, the knapsack problem, the shift optimization problem, and the delivery planning problem.

The above-described combinatorial optimization problem is described, for example, in Ising model form. The Ising model is a statistical mechanical model that represents the behavior of a magnetic material by its individual spins. In the Ising model, the orientation of each spin is represented by “1” or “−1”. The Ising model can formulate many combinatorial optimization problems.

When the combinatorial optimization problem is described in Ising model form, the equation representing the energy in the combinatorial optimization problem is first generated. Then, the equation representing the energy in the combinatorial optimization problem is converted to the energy function in the Ising model. The method of conversion to the energy function in the Ising model is well known. The energy function in the Ising model is represented as in the following Equation (1).

$$\begin{matrix}[ Math . 1 ] & \\ E = {\sum }_{i} {\sum }_{j} {J}_{ij} {s}_{i} {s}_{j} + {\sum }_{i} {h}_{i} {s}_{i} & Equation ( 1 )\end{matrix}$$

Both i and j in Equation (1) are variables representing spins. Also, sᵢ is a variable representing the orientation of spin i, and sⱼ is a variable representing the orientation of spin j in Equation (1). In other words, sᵢ and sⱼ are variables that are either “1” or “−1”.

Also, hᵢ in Equation (1) is a constant corresponding to spin i. For each possible value of i, hᵢ is determined as a constant. Jᵢⱼ in Equation (1) is a constant corresponding to the combination of spin i and spin j. For each possible combination of values of i and j, Jᵢⱼ is determined as a constant.

Instead of the energy function in the Ising model, a QUBO (Quadratic Unconstrained Binary Optimization) energy function may be used. QUBO is a model that represents the orientation of each spin by “1” or “0”.

That is, the equation representing the energy in a combinatorial optimization problem can be converted to an energy function in QUBO. This conversion method is well known. The energy function in the Ising model and the energy function in QUBO are mutually convertible.

Given the energy function shown in Equation (1), the optimal individual spin orientation (1 or −1) is found when the combinatorial optimization problem is solved. The optimal individual spin orientations found represent the solution to the combinatorial optimization problem.

For example, many combinatorial optimization problems can be attributed to minimization problems which are the problems of finding a combination that minimizes an arbitrary objective function (minimization target) under given constraints. When the combinatorial optimization problem is a minimization problem, the optimal individual spin orientation is the orientation of the individual spins such that the energy E indicated by the energy function is as small as possible.

The combinatorial optimization problem described in Ising model form is solved, for example, by a simulated annealing scheme (hereinafter referred to as the SA scheme). Non Patent Literature (NPL) 1 describes a parallelized simulated annealing algorithm when applied to the placement of modules in a VLSI (Very Large Scale Integration) circuit.

### CITATION LIST

### Non Patent Literature

NPL 1: Jonas Knopman and Julio S. Aude, “Parallel simulated annealing: An adaptive approach,” In Proceedings 11th International Parallel Processing Symposium, 1997.

### SUMMARY OF INVENTION

### Technical Problem

When solving a combinatorial optimization problem, the SA scheme accepts a spin flip if the energy when the spin is flipped (turnover) is lowered. The SA scheme does not accept a spin flip if the energy when the spin is flipped increases.

The SA scheme repeatedly executes the above process thousands, tens of thousands, or more than tens of thousands of times with different spins. By repeated execution, the SA scheme finds the optimal solution to the combinatorial optimization problem.

However, since each spin has a dependency, it is difficult to simultaneously compute whether multiple spin flips are accepted or not. In other words, it is difficult to efficiently parallelize the iterative process by the SA scheme. Efficient parallelization of the iterative process by the SA scheme has not been described in NPL 1.

Therefore, it is an object of the present invention to provide a simulated annealing device, a simulated annealing method, and a simulated annealing program that can efficiently parallelize the iterative process by the simulated annealing scheme.

### Solution to Problem

A simulated annealing device according to the present invention is a simulated annealing device for solving a combinatorial optimization problem by a simulated annealing scheme, includes a confirmation means which executes a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n, an updating means which, when the acceptance of a flip on m-th spin (m is an integer between {(k−1)·n+1} and k·n) is confirmed first, updates change amount in energy of a spin associated with the m-th spin with the m-th spin flipped, and a changing means which changes spins in which the next process of confirming is executed and the parallel number to spins from (m+1)-th to k n-th and (n−m), respectively.

A simulated annealing method according to the present invention is a simulated annealing method for solving a combinatorial optimization problem by a simulated annealing scheme, includes executing a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n, when the acceptance of a flip on m-th spin (m is an integer between {(k−1)·n+1} and k·n) is confirmed first, updating change amount in energy of a spin associated with the m-th spin with the m-th spin flipped, and changing spins in which the next process of confirming is executed and the parallel number to spins from (m+1)-th to k·n-th and (n−m), respectively.

A simulated annealing program according to the present invention is a simulated annealing program causing a computer for solving a combinatorial optimization problem by a simulated annealing scheme to execute a parallel process of executing a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n, a updating process of, when the acceptance of a flip on m-th spin (m is an integer between {(k−1)·n+1} and k·n) is confirmed first, updating change amount in energy of a spin associated with the m-th spin with the m-th spin flipped, and a changing process of changing spins in which the next process of confirming is executed and the parallel number to spins from (m+1)-th to k·n-th and (n−m), respectively.

### Advantageous Effects of Invention

According to the present invention, it is possible to efficiently parallelize the iterative process by the simulated annealing scheme.

### BRIEF DESCRIPTION OF DRAWING

FIG. 1 is a flowchart showing an operation of the combinatorial optimization problem solving process by the general SA scheme.

FIG. 2 is an explanatory diagram showing an example of parallelization of the combinatorial optimization problem solving process by the general SA scheme.

FIG. 3 is a block diagram showing an example of the configuration of a simulated annealing device of the example embodiment of the present invention.

FIG. 4 is an explanatory diagram showing an example of parallelization of the combinatorial optimization problem solving process by the simulated annealing device 100.

FIG. 5 is an explanatory diagram showing an example of the parallel process by the general SA scheme and the parallel process by the simulated annealing device 100.

FIG. 6 is an explanatory diagram showing another example of the parallel process by the general SA scheme and the parallel process by the simulated annealing device 100.

FIG. 7 is an explanatory diagram showing another example of the parallel process by the general SA scheme and the parallel process by the simulated annealing device 100.

FIG. 8 is a flowchart showing an operation of the combinatorial optimization problem solving process by the simulated annealing device 100 of the present example embodiment.

FIG. 9 is an explanatory diagram showing an example of a hardware configuration of a simulated annealing device according to the present invention.

FIG. 10 is a block diagram showing an overview of a simulated annealing device according to the present invention.

### DESCRIPTION OF EMBODIMENTS

First, we will explain a content of the above-described problem specifically. The SA scheme is a general-purpose method for solving combinatorial optimization problems in an approximate manner. The SA scheme solves combinatorial optimization problems with the following four processes as one cycle.
1. select one spin
2. compute the change amount in energy Δ when flipping the selected spin
3. with probability min(exp(−Δ/T),1), accept spin flip
4. if the flip is accepted, flip the selected spin

Specifically, the SA scheme flips the spin orientation selected in step 2 above from −1 to 1 or 1 to −1, and computes the change amount Δ in energy when flipping the spin.

Then, if the computed Δ is negative, the SA scheme accepts the spin flip in step 3 above. If the computed Δ is positive, the SA scheme accepts the spin flip with the probability computed as above.

Then, the SA scheme flips the spin selected in step 4 above if the flip is accepted.

In other words, the SA scheme does not accept the spin flip according to the result of the computation in step 3. If the spin flip is not accepted, the selected spin is not flipped and remains in its original state.

The SA scheme finds the combination of spin orientations that minimizes the energy E by repeatedly performing process of steps 1 to 4 above (hereinafter also referred to as the iterative process).

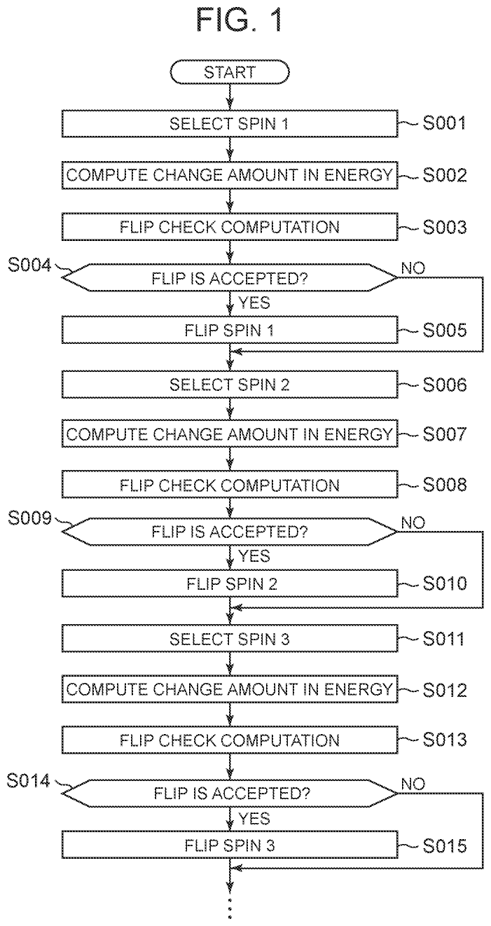

FIG. 1 is a flowchart showing an operation of the combinatorial optimization problem solving process by the general SA scheme.

First, the SA scheme selects spin 1 (step S001). Next, the SA scheme computes the change amount Δ in energy when flipping the spin 1 (step S002). Next, the SA scheme executes a flip check computation, which is the computation required to determine whether a flip of spin 1 is accepted or not (e.g., computation of probability min(exp(−Δ/T),1)) (step S003).

Next, the SA scheme decides whether or not to accept the flip of spin 1 according to the result of the computation in step S003 (step S004). If it is decided to accept the flip (Yes in step S004), the SA scheme flips spin 1 (step S005). If it is decided not to accept the flip (No in step S004), the SA scheme proceeds to step S006.

In other words, regardless of the result, the SA scheme decides whether to accept or not the flip of spin 1, and then selects the next spin 2 (step S006). After step S006, the SA scheme repeats the same process as steps S001-S005.

As shown in FIG. 1, the SA scheme selects one spin and decides whether to accept or not the flip of the selected spin. In other words, according to whether the flip of the previously selected spin is accepted or not, the flip of the next selected spin is also accepted or not. Therefore, it is difficult to parallelize the iterative process by the SA scheme.

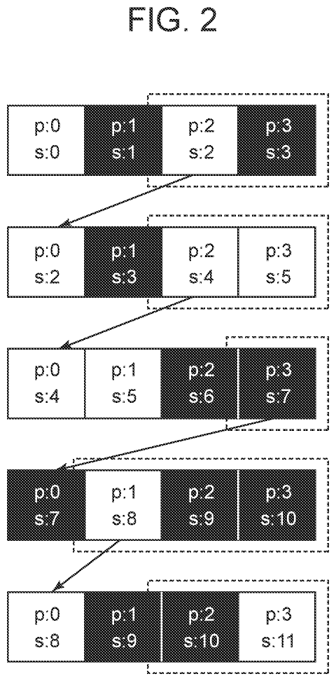

FIG. 2 is an explanatory diagram showing an example of parallelization of the combinatorial optimization problem solving process by the general SA scheme. The example shown in FIG. 2 is an example in which the combinatorial optimization problem solving process is accelerated by parallelizing the process with spins because of the high load of the process of computing the change amount Δ in energy.

One rectangle shown in FIG. 2 represents the above one iterative process. The “p” and “s” in the rectangle shown in FIG. 2 represent the process number and spin number, respectively. The black rectangle shown in FIG. 2 represents the process in which the spin flip is accepted. The rectangle enclosed in a dashed rectangle shown in FIG. 2 represents a process that is wasted.

For example, the four rectangles shown in the top row of FIG. 2 represent a parallel process in where a process with process number 0 for a spin with spin number 0, a process with process number 1 for a spin with spin number 1, a process with process number 2 for a spin with spin number 2, and a process with process number 3 for a spin with spin number 3, are executed in parallel with parallel number 4.

The four rectangles shown in the top row of FIG. 2 represent that a spin flip with spin number 1 is accepted for a process with process number 1, and that a spin flip with spin number 3 is accepted for a process with process number 3.

In other words, since the spin flip with spin number 1 is accepted by the process with process number 1, the iterative process for spins after the spin with spin number 2 is required to be started over again with the spin with spin number 1 flipped.

Therefore, as shown in the top row of FIG. 2, the process with process number 2 and the process with process number 3 are both wasted. The spin with spin number 3 also remains in its original state. In other words, in the parallelization of the combinatorial optimization problem solving process by the SA scheme, the state of a spin may not change even if the spin flip is accepted.

After a spin is flipped, the SA scheme redoes the iterative process starting from the next spin after the spin that was flipped. As shown in the second row of FIG. 2, the SA scheme uses the process with process number 0 as the process for the spin with spin number 2.

The SA scheme executes a process with process number 0 for a spin with spin number 2, a process with process number 1 for a spin with spin number 3, a process with process number 2 for a spin with spin number 4, and a process with process number 3 for a spin with spin number 5 in parallel with parallel number 4.

The contents shown in the second and subsequent rows of FIG. 2 are the same as those shown in the top row. As shown in FIG. 2, when flips are frequently accepted, more process is wasted.

To shorten the process time as much as possible, the SA scheme may compute only the process “2. compute the change amount in energy Δ when flipping the selected spin” in the iterative process in parallel over all spins first. If the SA scheme a process of step 2 executes first, it solves the combinatorial optimization problem using the following four processes as the iterative process.
11. select one spin
12. with probability min(exp(−Δ/T),1), accept spin flip
13. if the flip is accepted, flip the selected spin
14. update the change amount in energy Δ of the associated spin

In other words, the iterative process described above is a process that computes the change amount in energy first and updates the change amount in energy for the spin associated with the flipped spin only if the spin is flipped.

However, the amount of operations per processes of steps 11-14 is not large. Therefore, even if multiple iterative processes are executed in parallel in a multi-process or multi-threading method, where memory is shared and each process or thread executes iterative processes in parallel and then synchronization is taken, the overhead due to synchronization is more dominant in the overall process. In other words, the effect of parallelization by the multi-process or multi-threading method is small.

The following is a description, with reference to the drawings, of an example embodiment of the present invention that can reduce wasted process when flips are frequently accepted and can reduce the effect of overhead due to synchronization in the overall combinatorial optimization problem solving process.

### [Description of Configuration]

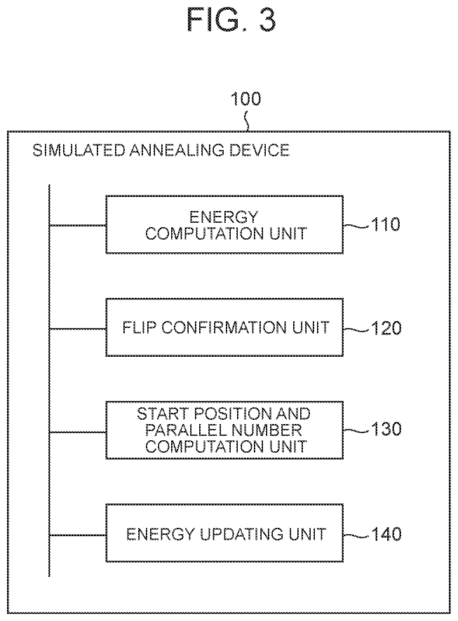

FIG. 3 is a block diagram showing an example of the configuration of a simulated annealing device of the example embodiment of the present invention.

As shown in FIG. 3, a simulated annealing device 100 of this example embodiment includes an energy computation unit 110, a flip confirmation unit 120, a start position and parallel number computation unit 130, and an energy updating unit 140.

The simulated annealing device 100 of this example embodiment uses a method of computing the change amount Δ in energy due to spin flips in parallel over all spins first, and then solving the combinatorial optimization problem as a single cycle of four processes from steps 11 to 14.

The energy computation unit 110 has the function of computing the change amount Δ in energy due to spin flips over all spins in parallel.

The flip confirmation unit 120 has the function of executing processes of steps 11-13 in parallel. That is, the flip confirmation unit 120 selects a spin and accepts the spin flip with probability min(exp(−Δ/T),1). If the flip is accepted, the flip confirmation unit 120 flips the selected spin.

The start position and parallel number computation unit 130 has the function of computing the position of spin to start the next parallel process and the parallel number of parallel process based on the results of processes of steps 11 to 13.

The energy updating unit 140 has the function of executing the process of step 14 in parallel. That is, the energy updating unit 140 updates the change amount in energy of the spin associated with the flipped spin in parallel only when the spin is flipped.

The simulated annealing device 100 of this example embodiment is characterized by the fact that parallelization is realized with vector arithmetic units. For example, the flip confirmation unit 120 and the energy updating unit 140 are realized with vector arithmetic units.

Unlike multi-process and multi-threading, the vector arithmetic unit is a device specialized for parallel process from the beginning. Parallelization by the vector arithmetic unit is not affected by overhead due to synchronization. In addition, because the vector arithmetic unit can change the parallelization target, the vector arithmetic unit can parallelize both the process by the flip confirmation unit 120 and the process by the energy updating unit 140.

The simulated annealing device 100 of this example embodiment has the feature of reducing the wasted process shown in FIG. 2 by fixing the iteration width. When the parallel number is reduced by reducing wasted process, the flip confirmation unit 120 and the energy updating unit 140, which are realized by vector arithmetic units, can execute the parallel process faster.

The advantages of reducing the parallel number are explained below. When the parallel process is executed in multi-process or multi-threading, the process speed generally does not change significantly even if the parallel number is changed. For example, the time in which process X is executed in one process and the time in which process X is divided into four and executed in parallel in four processes may be approximately equal.

The process speed differs according to the parallel number, even when the process is executed in a vector arithmetic unit or when the time for each divided process is short, etc. For example, depending on the conditions, the time in which process X is divided into four and executed in parallel in four processes may be longer than the time in which process X is executed in one process.

Therefore, the process time of the parallel process may be shorter if the parallel number is reduced without wasted operations. In addition, the parallel process itself is executed more efficiently. For the parallel process shown in the top row of FIG. 2, the process with process number 2 and the process with process number 3 are both wasted processes. Since the parallel process with a parallel number of 2 is more likely to have a shorter process time than the parallel process with a parallel number of 4, it is preferable that the parallel number be reduced from 4 to 2.

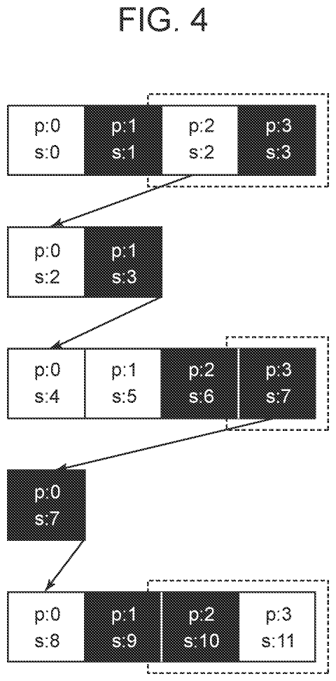

FIG. 4 is an explanatory diagram showing an example of parallelization of the combinatorial optimization problem solving process by the simulated annealing device 100.

The content represented by the four rectangles shown in the top row of FIG. 4 is the same as that represented by the four rectangles shown in the top row of FIG. 2. As shown in the top row of FIG. 4, the process with process number 2 and the process with process number 3 are both wasted.

As shown in the second row of FIG. 4, the simulated annealing device 100 of this example embodiment executes in parallel only the remaining two processes that require redoing among the processes represented by the four rectangles shown in the top row, by reducing the parallel number from four to two.

In this example embodiment, “fixing the iteration width” indicates that the iterative process is not executed for the next spin until the orientation of all spins subject to the parallel process is determined. In the example shown in FIG. 4, the fixed width is set to 4. The start position and parallel number computation unit 130 executes the computation of the position of the spin to be restarted for the parallel process and the update of the parallel number.

Therefore, as shown in the second row of FIG. 4, the simulated annealing device 100 executes the process with process number 0 for the spin with spin number 2 and the process with process number 1 for the spin with spin number 3 in parallel with the parallel number 2. As shown in the second row of FIG. 4, if a spin flip is accepted in the last process of the parallel process, the next parallel process is not affected.

Since the orientation of all four spins of spin numbers 0 to 3, which were initially subject to the parallel process at the end of the parallel process shown in the second row of FIG. 4, has been determined, the simulated annealing device 100 executes the parallel process for the next four spins of spin numbers 4 to 7.

As shown in the third row of FIG. 4, the spin flip with spin number 6 has been accepted for the process with process number 2. Therefore, as shown in the fourth row of FIG. 4, the simulated annealing device 100 executes in parallel the process with process number 0 for the spin with spin number 7, which corresponds to the remaining process that be requested to be redone among the processes represented by the four rectangles shown in the third row, with the parallel number reduced from 4 to 1.

Since the orientation of all four spins of spin numbers 4 to 7, which were subject to the parallel process for the second time at the end of the parallel process shown in the fourth row of FIG. 4, has been determined, the simulated annealing device 100 executes the parallel process for the next four spins of spin numbers 8 to 11.

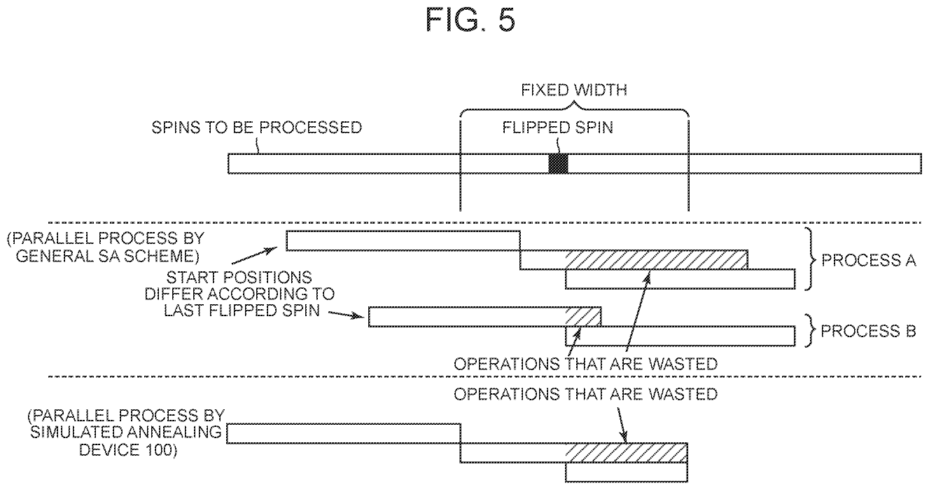

The following is an explanation of the effects of the simulated annealing device 100 of this example embodiment. FIG. 5 is an explanatory diagram showing an example of the parallel process by the general SA scheme and the parallel process by the simulated annealing device 100.

The elongated rectangle shown in the top row of FIG. 5 represents the spins to be processed, arranged in order. The black rectangle also represents the flipped spin, which is the spin for which flip is accepted. The length between the vertical lines represents the fixed width.

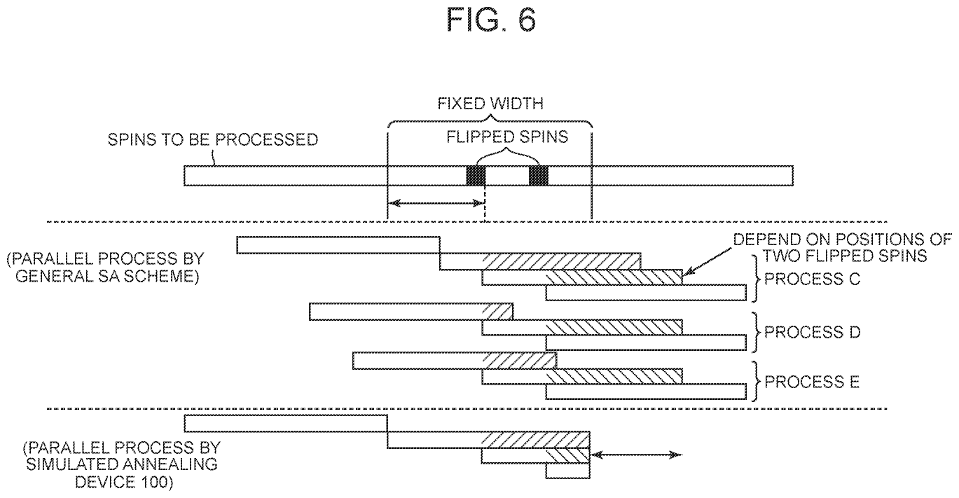

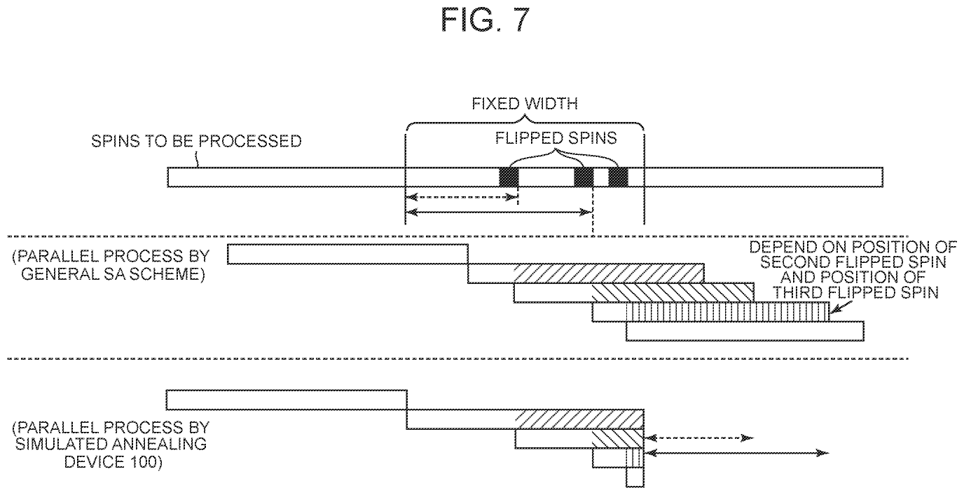

In other words, the example shown in FIG. 5 is an example of a case where there is one flipped spin within the fixed width. The meaning of each notation shown in FIG. 5 is the same in FIGS. 6-7.

The elongated rectangles shown in the middle row of FIG. 5 represent the parallel process by the general SA scheme. As shown in the middle row of FIG. 5, in the general SA scheme, the start position of parallel process differs according to the position of the last flipped spin.

The shaded rectangles shown in FIG. 5 represent operations that are wasted. The amount of operations that are wasted changes as the start position of parallel process differs. For example, in process A shown in FIG. 5, after the first parallel process is completed, the forward spin of the target of the second parallel process is flipped. In other words, the amount of operations that are wasted is relatively large.

Also, for example, in process B shown in FIG. 5, the backward spin of the target of the first parallel process is flipped. In other words, the amount of operations that are wasted is relatively small.

The elongated rectangles shown in the bottom row of FIG. 5 represent the parallel process by the simulated annealing device 100. In parallel process by the simulated annealing device 100, the start position of parallel process does not differ regardless of the position of the last flipped spin.

Since the start position of parallel process does not differ, the amount of operations that are wasted does not change. For example, in the process shown in the bottom row of FIG. 5, after the first parallel process is completed, the center spin (flipped spin) of the target of the second parallel process is flipped. The simulated annealing device 100 executes the remaining parallel process using the next spin after the flipped spin as the start position. In other words, the amount of operations that are wasted is determined solely by the position of the flipped spin.

If the start position of parallel process by the general SA scheme is between the first vertical line and the flipped spin (e.g., in the case of process A), the simulated annealing device 100 can reduce the amount of operations that are wasted. In other words, when there is one flipped spin within the fixed width, the probability that the simulated annealing device 100 can reduce the amount of operations that are wasted compared to the general SA scheme is 50%.

FIG. 6 is an explanatory diagram showing another example of the parallel process by the general SA scheme and the parallel process by the simulated annealing device 100. As shown in the top row of FIG. 6, there are two flipped spins in the spins to be processed in this example.

The elongated rectangles shown in the middle row of FIG. 6 represent the parallel process by the general SA scheme. The right-up shaded rectangles shown in FIG. 6 represent operations that are wasted due to the first flipped spin. As shown in the middle row of FIG. 6, as in the example shown in FIG. 5, the amount of operations that are wasted due to the first flipped spin changes as the start position of parallel process differs.

The right-declined shaded rectangles shown in FIG. 6 represents the operations that are wasted due to the second flipped spin. In all of the processes C-E shown in FIG. 6, the amount of operations that are wasted due to the second flipped spin is the same because the parallel process is restarted from the next spin after the first flipped spin. In other words, the amount of operations that are wasted due to the second flipped spin is determined by the positions of the two flipped spins.

The elongated rectangles shown in the bottom row of FIG. 6 represent the parallel process by the simulated annealing device 100. In the process shown in the bottom row of FIG. 6, after the first parallel process is completed, the center spin (the first flipped spin) of the target of the second parallel process is flipped. The simulated annealing device 100 executes the remaining parallel process using the next spin after the first flipped spin as the start position.

The center spin (the second flipped spin) of the target of the third parallel process is flipped. The simulated annealing device 100 executes the remaining parallel process using the next spin after the second flipped spin as the start position.

When there are two flipped spins within a fixed width, the simulated annealing device 100 can always reduce the amount of the length of both end arrows among the amount of operations that are wasted due to the second flipped spin, as shown in FIG. 6, compared to the general SA scheme. The length of both end arrows corresponds to the length from the first vertical line to the position of the first flipped spin.

As described above, unlike the example shown in FIG. 5, in the example with two flipped spins within the fixed width shown in FIG. 6, the simulated annealing device 100 can always reduce the amount of operations that are wasted due to flipped spins compared to the general SA scheme.

FIG. 7 is an explanatory diagram showing another example of the parallel process by the general SA scheme and the parallel process by the simulated annealing device 100. As shown in the top row of FIG. 7, there are three flipped spins in the spins to be processed in this example.

The elongated rectangles shown in the middle row of FIG. 7 represent the parallel process by the general SA scheme. The right-up shaded rectangles shown in FIG. 7 represent operations that are wasted due to the first flipped spin. As in the example shown in FIG. 5, the amount of operations that are wasted due to the first flipped spin differs according to the start position of the first parallel process.

The right-declined shaded rectangles shown in FIG. 7 represent the operations that are wasted due to the second flipped spin. Since the second parallel process is restarted from the next spin after the first flipped spin, the amount of operations that are wasted due to the second flipped spin is invariant.

The rectangles with the vertical line shown in FIG. 7 represents the operations that are wasted due to the third flipped spin. Since the third parallel process is restarted from the next spin after the second flipped spin, the amount of operations that are wasted due to the third flipped spin is invariant. The amount of operations that are wasted due to the third flipped spin is determined by the position of the second flipped spin and the position of the third flipped spin.

The elongated rectangles shown in the bottom row of FIG. 7 represent the parallel process by the simulated annealing device 100. In the process shown in the bottom row of FIG. 7, after the first parallel process is completed, the center spin (the first flipped spin) of the target of the second parallel process is flipped. The simulated annealing device 100 executes the remaining parallel process using the next spin after the first flipped spin as the start position.

The center spin (the second flipped spin) of the target of the third parallel process is flipped. The simulated annealing device 100 executes the remaining parallel process using the next spin after the second flipped spin as the start position.

The center spin (the third flipped spin) of the target of the fourth parallel process is flipped. The simulated annealing device 100 executes the remaining parallel process using the next spin after the third flipped spin as the start position.

When there are three flipped spins within a fixed width, the simulated annealing device 100 can always reduce the amount of the length of the dashed double-ended arrows among the amount of operations that are wasted due to the second flipped spin, as shown in FIG. 7, compared to the general SA scheme. The length of the dashed double-ended arrows corresponds to the length from the first vertical line to the position of the first flipped spin.

Similarly, the simulated annealing device 100 can always reduce the amount of the length of both end arrows among the amount of operations that are wasted due to the third flipped spin, as shown in FIG. 7, compared to the general SA scheme. The length of both end arrows corresponds to the length from the first vertical line to the position of the second flipped spin.

As described above, unlike the example shown in FIG. 5, in the example shown in FIG. 7 where three flipped spins exist within the fixed width, the simulated annealing device 100 can always reduce the amount of operations that are wasted due to flipped spins compared to the general SA scheme. In addition, the more flipped spins exist within the fixed width, the more the simulated annealing device 100 can reduce the amount of operations that are wasted.

As described above, the simulated annealing device 100 of this example embodiment is a simulated annealing device that solves a combinatorial optimization problem by a simulated annealing scheme. The simulated annealing device 100 includes an energy computation unit 110, a flip confirmation unit 120, a start position and parallel number computation unit 130, and an energy updating unit 140.

The flip confirmation unit 120 executes the process of confirming whether a flip is accepted or not for each of the n spins from the {(k−1)·n+1}-th to k·n-th (k is an integer greater than or equal to 1, n is an integer greater than or equal to 2) that constitute the energy function in the Ising model representing the combinatorial optimization problem in parallel with the parallel number n.

The energy updating unit 140, when the acceptance of a flip on the m-th spin (m is an integer between {(k−1)·n+1} and k·n) is confirmed first, updates the change amount in energy of the spin associated with the m-th spin with the m-th spin flipped.

The start position and parallel number computation unit 130 changes the spins in which the next process of confirming is executed and parallel number to the spins from the (m+1)-th to k·n-th and (n−m), respectively.

The flip confirmation unit 120 executes the process of confirming for each of the n spins from the (k·n+1)-th to (k+1)·n-th in parallel with the parallel number n after it is determined whether the k·n-th spin flips or not.

The energy computation unit 110 computes the change amount in energy due to a spin flip across all spins that constitute the energy function, respectively. The flip confirmation unit 120 executes the first process of confirming after each change amount in energy is computed.

As mentioned above, the flip confirmation unit 120 and the energy updating unit 140 may be realized by vector arithmetic units. The combinatorial optimization problem may also be a traveling salesman problem.

### [Description of Operation]

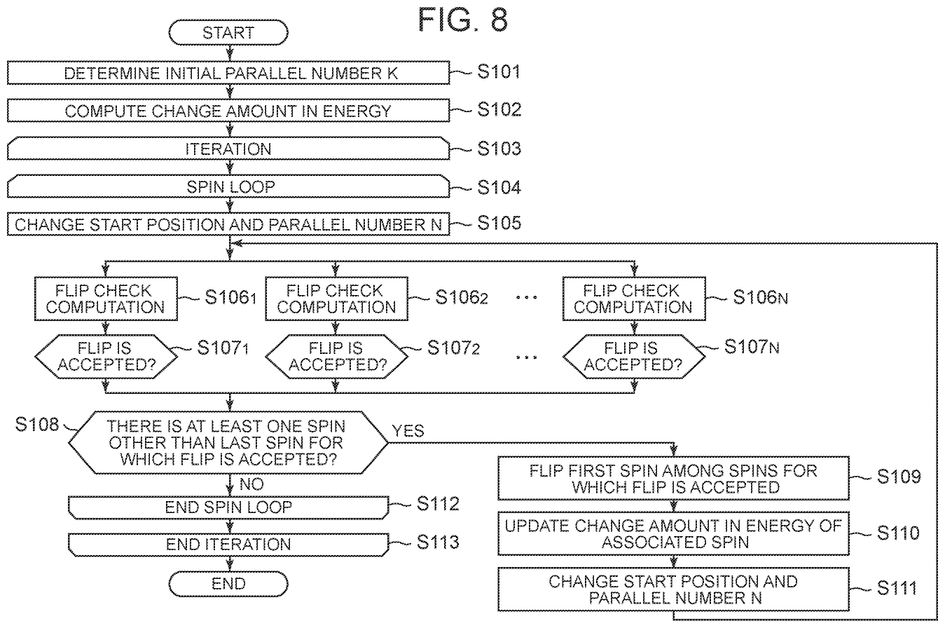

Hereinafter, the operation of the simulated annealing device 100 of this example embodiment will be described with reference to FIG. 8. FIG. 8 is a flowchart showing an operation of the combinatorial optimization problem solving process by the simulated annealing device 100 of the present example embodiment.

First, a combinatorial optimization problem described in Ising model form is input to the simulated annealing device 100.

The start position and parallel number computation unit 130 determines the initial parallel number K (K is an integer greater than or equal to 2) for parallel process when solving the input combinatorial optimization problem using the SA scheme (step S101).

Next, the energy computation unit 110 computes the change amount in energy due to a spin flip across all spins that constitute the energy function in the Ising model in parallel (step S102). Next, the simulated annealing device 100 enters iteration (step S103).

Next, the simulated annealing device 100 enters a spin loop (step S104). Next, the start position and parallel number computation unit 130 changes the start position of the parallel process and the parallel number N (N is an integer greater than or equal to 2) (step S105).

In the first spin loop, the start position and parallel number computation unit 130 sets the start position of the parallel process to the first spin. The start position and parallel number computation unit 130 also sets the parallel number N to the initial parallel number K.

Next, the flip confirmation unit 120 executes flip check computations in parallel for each of the K spins from the first to the K-th (steps S106₁ to S106_{N}).

Next, the flip confirmation unit 120 decides in parallel whether to accept or not the flip for each of the K spins from the first to the K-th (steps S107₁ to S107_{N}).

Next, the flip confirmation unit 120 checks whether there is at least one spin other than the last (K-th) spin for which a flip is accepted (step S108).

If there is at least one spin for which a flip is accepted other than the last (Yes in step S108), the flip confirmation unit 120 flips the first spin among the spins for which a flip is accepted (step S109).

Next, the energy updating unit 140 updates the change amount in energy of the spin associated with the flipped spin in parallel (step S110).

Next, the start position and parallel number computation unit 130 changes the start position of parallel process and the parallel number N (step S111). For example, if the first spin among the spins for which a flip is accepted is the M-th spin (M is an integer between 1 and K), the start position and parallel number computation unit 130 changes the start position of parallel process to the (M+1)-th spin.

The start position and parallel number computation unit 130 changes the parallel number N to (K-M). After changing the start position and the parallel number N, the flip confirmation unit 120 executes processes of steps S106₁ to S106_{N} again in parallel.

For example, the flip confirmation unit 120 executes flip check computations in parallel for each of the (K-M) spins from the (M+1)-th to the K-th (steps S106₁ to S106_{N}).

The flip confirmation unit 120 also decides in parallel whether to accept or not the flip for each of the (K-M) spins from the (M+1)-th to the K-th (steps S107₁ to S107_{N}).

If there is not a single spin for which a flip is accepted other than the last (No in step S108), the start position and parallel number computation unit 130 executes a process of step S105 again.

When starting the second spin loop, the start position and parallel number computation unit 130 changes the start position of parallel process to the (K+1)-th spin. In addition, the start position and parallel number computation unit 130 changes the parallel number N to the initial parallel number K (step S105).

The simulated annealing device 100 repeatedly executes processes of steps S105 to S111 while there are spins whose orientations have not yet been determined among the spins that constitute the energy function in the Ising model. When the orientations of all spins have been determined, the simulated annealing device 100 exits the spin loop (step S112).

The simulated annealing device 100 repeatedly executes processes of steps S104 to S112 until, for example, the number of iterations reaches a predetermined number (thousands, tens of thousands, etc.). When the number of iterations reaches the predetermined number, the simulated annealing device 100 exits iteration (step S113) and terminates the combinatorial optimization problem solving process.

### Description of Effect

In the simulated annealing device 100 of this example embodiment, when the spins subject to the parallel process are flipped, the start position and parallel number computation unit 130 changes the start position of parallel process and the parallel number. After the start position and the parallel number are changed, the remaining parallel process is executed.

By executing parallel process while changing the parallel number as described above, the simulated annealing device 100 can reduce the amount of operations that are wasted compared to the general SA scheme as more spin flips are accepted. Therefore, the simulated annealing device 100 can efficiently parallelize the iterative processes by the simulated annealing scheme.

The flip confirmation unit 120 and the energy updating unit 140 of the simulated annealing device 100 of this example embodiment may be realized with vector arithmetic units. By being realized with vector arithmetic units, the effect of overhead caused by synchronization, which has occurred in parallelization by multi-process and multi-threading, is eliminated.

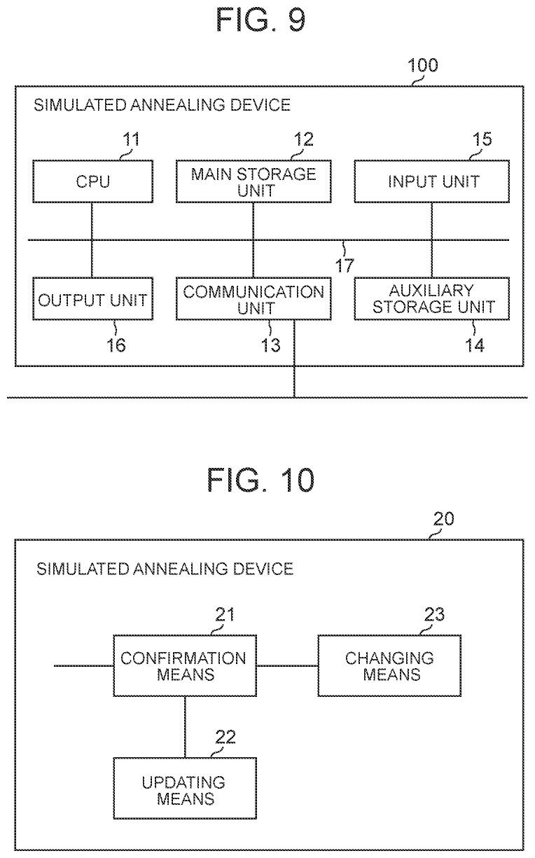

A specific example of a hardware configuration of the simulated annealing device 100 according to this example embodiment will be described below. FIG. 9 is an explanatory diagram showing an example of a hardware configuration of a simulated annealing device according to the present invention.

The simulated annealing device 100 shown in FIG. 9 includes a CPU (Central Processing Unit) 11, a main storage unit 12, a communication unit 13, and an auxiliary storage unit 14. The simulated annealing device 100 also includes an input unit 15 for the user to operate and an output unit 16 for presenting a processing result or a progress of the processing contents to the user.

The simulated annealing device 100 is realized by software, with the CPU 11 shown in FIG. 9 executing a program that provides a function that each component has.

Specifically, each function is realized by software as the CPU 11 loads the program stored in the auxiliary storage unit 14 into the main storage unit 12 and executes it to control the operation of the simulated annealing device 100.

The simulated annealing device 100 shown in FIG. 9 may include a DSP (Digital Signal Processor) instead of the CPU 11. Alternatively, the simulated annealing device 100 shown in FIG. 9 may include both the CPU 11 and the DSP.

The main storage unit 12 is used as a work area for data and a temporary save area for data. The main storage unit 12 is, for example, RAM (Random Access Memory).

The communication unit 13 has a function of inputting and outputting data to and from peripheral devices through a wired network or a wireless network (information communication network).

The auxiliary storage unit 14 is a non-transitory tangible medium. Examples of non-transitory tangible media are, for example, a magnetic disk, an optical magnetic disk, a CD-ROM (Compact Disk Read Only Memory), a DVD-ROM (Digital Versatile Disk Read Only Memory), a semiconductor memory.

The input unit 15 has a function of inputting data and processing instructions. The input unit 15 is, for example, an input device such as a keyboard or a mouse.

The output unit 16 has a function to output data. The output unit 16 is, for example, a display device such as a liquid crystal display device, or a printing device such as a printer.

As shown in FIG. 9, in the simulated annealing device 100, each component is connected to the system bus 17.

The auxiliary storage unit 14 stores programs for realizing the energy computation unit 110, the flip confirmation unit 120, the start position and parallel number computation unit 130 and the energy updating unit 140 in the simulated annealing device 100.

The simulated annealing device 100 may be implemented with a circuit that contains hardware components inside such as an LSI (Large Scale Integration) that realize the functions shown in FIG. 3, for example.

The simulated annealing device 100 may be realized by hardware that does not include computer functions using elements such as a CPU. For example, some or all of the components may be realized by a general-purpose circuit (circuitry) or a dedicated circuit, a processor, or a combination of these. They may be configured by a single chip (for example, the LSI described above) or by multiple chips connected via a bus. Some or all of the components may be realized by a combination of the above-mentioned circuit, etc. and a program.

Some or all of each component of the simulated annealing device 100 may be configured by one or more information processing devices which include a computation unit and a storage unit.

In the case where some or all of the components are realized by a plurality of information processing devices, circuits, or the like, the plurality of information processing devices, circuits, or the like may be centrally located or distributed. For example, the information processing devices, circuits, etc. may be realized as a client-server system, a cloud computing system, etc., each of which is connected via a communication network.

Next, an overview of the present invention will be explained. FIG. 10 is a block diagram showing an overview of a simulated annealing device according to the present invention. The simulated annealing device 20 according to the present invention is a simulated annealing device for solving a combinatorial optimization problem by a simulated annealing scheme, includes a confirmation means 21 (for example, the flip confirmation unit 120) which executes a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n, an updating means 22 (for example, the energy updating unit 140) which, when the acceptance of a flip on m-th spin (m is an integer between {(k−1)·n+1} and k·n) is confirmed first, updates change amount in energy of a spin associated with the m-th spin with the m-th spin flipped, and a changing means 23 (for example, the start position and parallel number computation unit 130) which changes spins in which the next process of confirming is executed and the parallel number to spins from (m+1)-th to k·n-th and (n−m), respectively.

With such a configuration, the simulated annealing device can efficiently parallelize the iterative process by the simulated annealing scheme.

The confirmation means 21 may also execute the process of confirming for each of n spins from (k·n+1)-th to (k+1)·n-th in parallel with the parallel number n after it is determined whether k·n-th spin flips or not.

With such a configuration, the simulated annealing device can efficiently parallelize the iterative process by the simulated annealing scheme.

The simulated annealing device 20 may also include a computation means (for example, the flip confirmation unit 120) which computes the change amount in energy due to a spin flip across all spins that constitute the energy function, respectively, and the confirmation means 21 may also execute the first process of confirming after each change amount in energy is computed.

With such a configuration, the simulated annealing device can solve combinatorial optimization problems faster.

The confirmation means 21 and the updating means 22 may also be realized by vector arithmetic units.

With such a configuration, the simulated annealing device can reduce the effect of overhead caused by synchronization in parallelization by multi-process and multi-threading.

The combinatorial optimization problem may also be a traveling salesman problem.

With such a configuration, the simulated annealing device can solve traveling salesman problems faster.

While the present invention has been explained with reference to the example embodiments and examples, the present invention is not limited to the aforementioned example embodiments and examples. Various changes understandable to those skilled in the art within the scope of the present invention can be made to the structures and details of the present invention.

Reference Signs List

| | |
|---|---|
| 11 | CPU |
| 12 | Main storage unit |
| 13 | Communication unit |
| 14 | Auxiliary storage unit |
| 15 | Input unit |
| 16 | Output unit |
| 17 | System bus |
| 20, 100 | Simulated annealing device |
| 21 | Confirmation means |
| 22 | Updating means |
| 23 | Changing means |
| 110 | Energy computation unit |
| 120 | Flip confirmation unit |
| 130 | Start position and parallel number computation unit |
| 140 | Energy updating unit |

What is claimed is:

1. A simulated annealing device for solving a combinatorial optimization problem by a simulated annealing scheme, comprising:
a memory configured to store instructions; and
a processor configured to execute the instructions to:
execute a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n;
when the acceptance of a flip on m-th spin (m is an integer between {(k−1)·n+1} and k·n) is confirmed first, update change amount in energy of a spin associated with the m-th spin with the m-th spin flipped; and
change spins in which the next process of confirming is executed and the parallel number to spins from (m+1)-th to k·n-th and (n−m), respectively.

2. The simulated annealing device according to claim 1, wherein the processor is further configured to execute the instructions to:
execute the process of confirming for each of n spins from (k·n+1)-th to (k+1)·n-th in parallel with the parallel number n after it is determined whether k·n-th spin flips or not.

3. The simulated annealing device according to claim 1, wherein the processor is further configured to execute the instructions to:
compute the change amount in energy due to a spin flip across all spins that constitute the energy function, respectively, wherein
execute the first process of confirming after each change amount in energy is computed.

4. (canceled)

5. The simulated annealing device according to claim 1, wherein
the combinatorial optimization problem is a traveling salesman problem.

6. A simulated annealing method for solving a combinatorial optimization problem by a simulated annealing scheme, comprising:
executing a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n;
when the acceptance of a flip on m-th spin (m is an integer between {(k−1)·n+1} and k·n) is confirmed first, updating change amount in energy of a spin associated with the m-th spin with the m-th spin flipped; and
changing spins in which the next process of confirming is executed and the parallel number to spins from (m+1)-th to k·n-th and (n−m), respectively.

7. The simulated annealing method according to claim 6, further comprising:
executing the process of confirming for each of n spins from (k·n+1)-th to (k+1) ·n-th in parallel with the parallel number n after it is determined whether k·n-th spin flips or not.

8. A computer-readable recording medium recording a simulated annealing program causing a computer for solving a combinatorial optimization problem by a simulated annealing scheme, to execute:
executing a process of confirming whether a flip is accepted or not for each of n spins from {(k−1)·n+1}-th to k·n-th (k is an integer greater than or equal to 1, n is an integer greater than or equal to 2) that constitute an energy function in the Ising model representing the combinatorial optimization problem in parallel with a parallel number n;
when the acceptance of a flip on m-th spin (m is an integer between {(k−1)·n+1} and k·n) is confirmed first, updating change amount in energy of a spin associated with the m-th spin with the m-th spin flipped; and
changing spins in which the next process of confirming is executed and the parallel number to spins from (m+1)-th to k·n-th and (n−m), respectively.

9. The recording medium recording the simulated annealing program according to claim 8, causing the computer to execute:
executing the process of confirming for each of n spins from (k·n+1)-th to (k+1)·n-th in parallel with the parallel number n after it is determined whether k·n-th spin flips or not.
